(19) United States
(12) Patent Application Publication
(10) Pub. No.: US 2025/0017093 A1
(43) Pub. Date: Jan. 9, 2025

(54) DISPLAY PANEL

(71) Applicants: Samsung Display Co., Ltd., Yongin-si (KR); Postech Research and Business Development Foundation, Pohang-si (KR)

(72) Inventors: Sungsoon IM, Yongin-si (KR); Jong Kyu KIM, Pohang-si (KR); Jeong Hyeon PARK, Pohang-si (KR); Heemin PARK, Yongin-si (KR); Seungyong SONG, Yongin-si (KR); Hyeon Woong HWANG, Pohang-si (KR)

(73) Assignees: Samsung Display Co., Ltd., Yongin-si (KR); Postech Research and Business Development Foundation, Pohang-si (KR)

(21) Appl. No.: 18/607,908

(22) Filed: Mar. 18, 2024

(30) Foreign Application Priority Data
Jul. 3, 2023 (KR) 10-2023-0086002

(51) Int. Cl. H10K 71/18; H10K 59/12; H10K 71/10

(52) U.S. Cl. CPC H10K 71/18; H10K 59/1201; H10K 71/191

(57) ABSTRACT

A method for manufacturing a display device includes providing a display substrate including a base substrate having a pixel region and including a first surface and a second surface, which are placed opposite to each other, providing a donor substrate including a base layer and a transfer layer disposed on the base layer and including an organic material such that the transfer layer is spaced apart from the base substrate by a distance, aligning the donor substrate and the display substrate such that the transfer layer faces the first surface of the base substrate, and transferring the transfer layer to the display substrate by irradiating a laser toward the donor substrate on the second surface of the base substrate.

CROSS-REFERENCE TO RELATED APPLICATION(S)

This application claims priority to and benefits of Korean Patent Application No. 10-2023-0086002 under 35 U.S.C. § 119, filed on Jul. 3, 2023, in the Korean Intellectual Property Office (KIPO), the entire contents of which are incorporated herein by reference.

### BACKGROUND

### 1. Technical Field

The disclosure herein relates to a device for manufacturing a display device, which uses a donor substrate having a simplified constitution, and a method for manufacturing the display device.

### 2. Description of Related Art

An organic light emitting element, as a flat panel display element, includes a first electrode, a second electrode, and a functional layer including at least an emission layer interposed between the first electrode and the electrode, and is equipped with favorable features such as wide viewing angles, high contrast ratio, and high response time, and is thus considered to be the preferred choice for next-generation display elements. The organic light emitting element may further include at least one functional layer among a hole injection layer, a hole transport layer, an electron transport layer, and an electron injection layer, in addition to the emission layer.

For full-color realization in the organic light emitting element, an organic layer needs to be patterned. Methods of patterning may include fine metal mask (FMM), laser induced thermal imaging (LITI), or laser induced pattern-wise sublimation (LIPS). The methods of LITI and LIPS provide benefits of finely patterning an organic layer, being usable for a large area, and achieving a high resolution.

### SUMMARY

The disclosure provides a method for manufacturing a display device, which uses a donor substrate having a simplified constitution, and a device for manufacturing a display device.

In an embodiment of the disclosure, a method for manufacturing a display device may include providing a display substrate including a base substrate having a pixel region and including a first surface and a second surface, which are placed opposite to each other, providing a donor substrate including a base layer and a transfer layer disposed on the base layer and including an organic material such that the transfer layer is spaced apart from the base substrate by a distance, aligning the donor substrate and the display substrate such that the transfer layer faces the first surface of the base substrate, and transferring the transfer layer to the display substrate by irradiating a laser toward the donor substrate on the second surface of the base substrate.

In an embodiment, the laser may have a wavelength in a range of about 0.8 μm to about 20 μm.

In an embodiment, the base layer may include at least one of glass, aluminum oxide (Al₂O₃), and aluminum oxynitride (AlON).

In an embodiment, the base layer may include a photothermal conversion material.

In an embodiment, the transfer layer may directly be disposed on the base layer.

In an embodiment, the base substrate may include at least one of silicon (Si), calcium fluoride (CaF₂), gallium arsenide (GaAs), and germanium (Ge).

In an embodiment, the transfer layer may include at least one of a hole transport material, a light emitting material, and an electron transport material.

In an embodiment, the display substrate may further include a metal pattern disposed on the base substrate and having an opening corresponding to the pixel region.

In an embodiment, the metal pattern may include at least one of gold (Au), silver (Ag), tungsten (W), and titanium (Ti).

In an embodiment, after the transferring of the transfer layer to the display substrate, an organic pattern may be formed in the opening.

In an embodiment, the method may further include removing the metal pattern after the transferring of the transfer layer to the display substrate.

In an embodiment, the display substrate may further include a first electrode disposed on the base substrate, and a pixel defining film disposed on the first electrode and having a pixel opening overlapping the pixel region in a plan view, and in the aligning of the donor substrate and the display substrate, the donor substrate may be disposed such that the transfer layer faces the first electrode.

In an embodiment, the transferring of the transfer layer to the display substrate may include transferring a hole transport region onto the first electrode, transferring an emission layer onto the hole transport region, and transferring an electron transport region onto the emission layer.

In an embodiment of the disclosure, a method for manufacturing a display device may include preparing a base substrate on which a pixel region is defined, forming a first electrode corresponding to the pixel region on a first surface of the base substrate, forming a pixel defining film on the first electrode such that the pixel defining film exposes a portion of the first electrode, disposing a donor substrate including a base layer and a transfer layer directly disposed on the base layer and including an organic material such that the transfer layer faces the first electrode, and forming an organic pattern on the first electrode from the transfer layer by irradiating a laser toward the donor substrate on a second surface placed opposite to the first surface of the base substrate.

In an embodiment, the base substrate and the donor substrate may be spaced apart from each other by a distance.

In an embodiment, the method may further include contacting the donor substrate to the base substrate prior to the forming of the organic pattern on the first electrode.

In an embodiment of the disclosure, a device for manufacturing a display device may include a stage on which a display substrate having a pixel region is placed, a donor substrate spaced apart from the display substrate and including a base layer and a transfer layer disposed on the base layer and including an organic material, and a laser irradiation portion spaced apart from the donor substrate with the display substrate between the laser irradiation portion and the donor substrate and irradiating the donor substrate with a laser on the display substrate.

In an embodiment, the laser irradiation portion may include a vertical cavity surface emitting laser (VCSEL).

In an embodiment, the laser irradiation portion may irradiate a portion of the donor substrate, which overlaps the pixel region in a plan view, with the laser.

In an embodiment, the laser irradiation portion may continuously move on the display substrate and irradiate the donor substrate with the laser.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIG. 2 is a schematic cross-sectional view of a display device according to an embodiment of the disclosure;

FIG. 3 is a perspective view schematically showing a device for manufacturing a display device according to an embodiment of the disclosure;

FIG. 4 is a flowchart showing a method for manufacturing a display device according to an embodiment of the disclosure;

FIGS. 5A to 5I are views schematically showing some processes in a method for manufacturing a display device according to an embodiment of the disclosure; and

FIGS. 6A to 6D are views schematically showing some processes in a method for manufacturing a display device according to an embodiment of the disclosure.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms (including technical and scientific terms) used herein have the same meaning as commonly understood by one of ordinary skill in the art to which the disclosure belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the disclosure will be described with reference to the accompanying drawings.

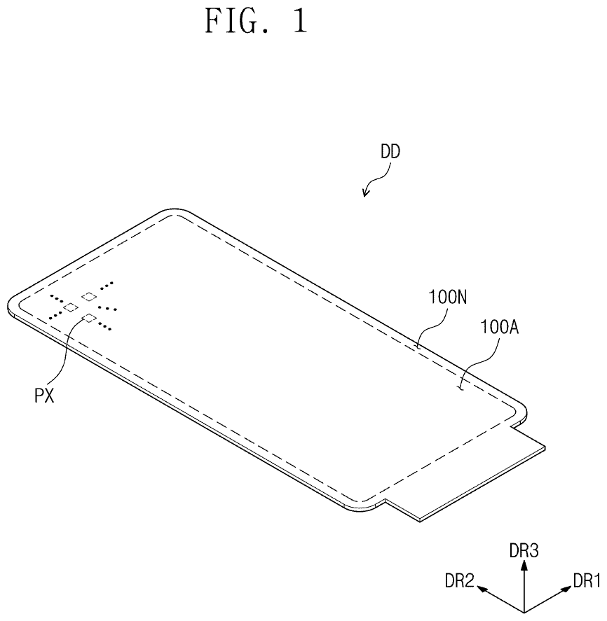

FIG. 1 is a perspective view of a display device according to an embodiment of the disclosure. A display device DD may generate images, and detect external inputs. The display device DD may include a display region 100A and a peripheral region 100N. A pixel PX may be disposed in the display region 100A. The pixel PX may include a first color pixel, a second color pixel, and a third color pixel, each generating light of different colors.

The display region 100A may display images. The display region 100A may include a plane defined by a first direction DR1 and a second direction DR2. The display region 100A may further include curved surfaces each bent from at least two sides of the plane. However, the shape of the display region 100A is not limited thereto. For example, the display region 100A may include only the plane, or the display region 100A may include curved surfaces each bent from at least two sides, for example, four sides of the plane.

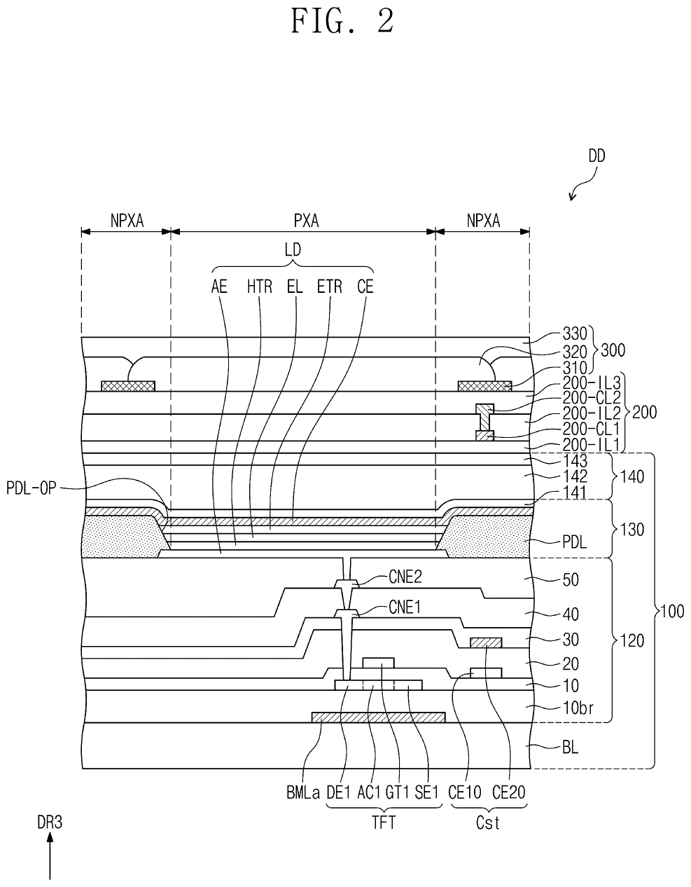

FIG. 2 is a schematic cross-sectional view of the display device DD according to the embodiment of the disclosure. FIG. 2 schematically shows a cross-section corresponding to one pixel region PXA and a peripheral region NPXA adjacent thereto. FIG. 2 schematically shows a light emitting element LD and a transistor TFT connected thereto. The transistor may be one of multiple transistors included in a driving circuit of the pixel PX. In the \ embodiment, the transistor TFT is described as a silicon transistor, but the disclosure is not limited thereto, and the transistor TFT may be a metal oxide transistor.

Referring to FIG. 2, the display device DD may include a display panel 100, an input sensor 200, and an anti-reflector 300.

The display panel 100 may be a light emitting display panel, and for example, the display panel 100 may be an organic light emitting display panel, an inorganic light emitting display panel, a micro LED display panel, or a nano LED display panel.

The display panel 100 may include a base substrate BL, a circuit layer 120, a light emitting element layer 130, and an encapsulation layer 140.

The base substrate BL may provide a base surface on which the circuit layer 120 is disposed. The base layer BS may be a rigid substrate, or a flexible substrate that is bendable, foldable, rollable, or the like. The base substrate BL may be a glass substrate, a metal substrate, or a polymer substrate. However, the embodiment of the disclosure is not limited thereto, and the base substrate BL may include an inorganic layer, an organic layer, or a composite material layer.

The base substrate BL may have a multi-layered structure. For example, the base substrate BL may include a first synthetic resin layer, a multi-or single-layered inorganic layer, and a second synthetic resin layer disposed on the multi-or single-layered inorganic layer. The first and second synthetic resin layers each may include a polyimide-based resin, but the disclosure is not particularly limited.

The circuit layer 120 may be disposed on the base substrate BL. The circuit layer 120 may include an insulating layer, a semiconductor pattern, a conductive pattern, and a signal line. The circuit layer 120 may include the driving circuit of the pixel PX described in FIG. 1.

A buffer layer 10br may be disposed on the base substrate BL. The buffer layer 10br may prevent diffusion of metal atoms or impurities from the base substrate BL into a semiconductor pattern. The semiconductor pattern may include an active region AC1 of the transistor TFT.

A back metal layer BMLa may be disposed below the transistor TFT. The back metal layer BMLa may block external light from reaching the transistor TFT. The back metal layer BMLa may be disposed between the base substrate BL and the buffer layer 10br. In an embodiment of the disclosure, a barrier layer of an inorganic layer may be further disposed between the back metal layer BMLa and the buffer layer 10br. The back metal layer BMLa may be connected to electrodes or lines, and may receive constant voltages or signals therefrom.

The semiconductor pattern may be disposed on the buffer layer 10br. The semiconductor pattern may include a silicon semiconductor. For example, the silicon semiconductor may include amorphous silicon, polycrystalline silicon, or the like. For example, the semiconductor pattern may include low-temperature polysilicon.

The semiconductor pattern may include a first region having high conductivity and a second region having low conductivity. The first region may be doped with an N-type dopant or a P-type dopant. A P-type transistor may include a doped region doped with a P-type dopant, and a N-type transistor may include a doped region doped with an N-type dopant. The second region may be a non-doped region or may be doped in a lower concentration than the first region.

The first region has greater conductivity than the second region, and may substantially serve as an electrode or a signal line. The second region may substantially correspond to an active region (or a channel) of the transistor. For example, a portion of the semiconductor pattern may be an active region of the transistor, another portion may be a source or drain of the transistor, and the other portion may be a connection electrode or a connection signal line.

A source region SE1 (or a source), an active region AC1 (or a channel), and a drain region DE1 (or a drain) of the transistor TFT may be formed from the semiconductor pattern. The source region SE1 and the drain region DE1 may extend in opposite directions from the active region AC1 in a cross-sectional view.

A first insulating layer 10 may be disposed on the buffer layer 10br. The first insulating layer 10 may commonly overlap multiple pixels PX (see FIG. 1) in a plan view and cover the semiconductor pattern. The first insulating layer 10 may include an inorganic layer and/or an organic layer, and have a single-layered or multi-layered structure. The inorganic layer may include at least one of aluminum oxide, titanium oxide, silicon oxide, silicon nitride, silicon oxynitride, zirconium oxide, and hafnium oxide. In an embodiment, the first insulating layer 10 may be a single-layered silicon oxide layer. Insulating layers of the circuit layer 120 which will be described below in addition to the first insulating layer 10 may be inorganic layers and/or organic layers, and have single-layer or multi-layer structures. The inorganic layer may include at least one of the materials described above, but the is not limited thereto.

A gate GT1 of the transistor TFT may be disposed on the first insulating layer 10. The gate GT1 may be a portion of a metal pattern. The gate GT1 may overlap the active region AC1 in a plan view. In the process of doping the semiconductor pattern, the gate GT1 may function as a mask. The gate GT1 may include at least one of titanium (Ti), silver (Ag), silver-containing alloy, molybdenum (Mo), molybdenum-containing alloy, aluminum (Al), aluminum-containing alloy, aluminum nitride (AlN), tungsten (W), tungsten nitride (WN), copper (Cu), indium tin oxide (ITO), indium zinc oxide (IZO), and the like, but the disclosure is not particularly limited thereto.

A second insulating layer 20 may be disposed on the first insulating layer 10 and may cover the gate GT1. A third insulating layer 30 may be disposed on the second insulating layer 20. A second electrode CE20 of the storage capacitor Cst may be disposed between the second insulating layer 20 and the third insulating layer 30. A first electrode CE10 of the storage capacitor Cst may be disposed between the first insulating layer 10 and the second insulating layer 20.

A first connection electrode CNE1 may be disposed on the third insulating layer 30. The first connection electrode CNE1 may be connected to drain region DEI of the transistor TFT through a contact hole passing through the first to third insulating layers 10, 20, and 30.

A fourth insulating layer 40 may be disposed on the third insulating layer 30. A second connection electrode CNE2 may be disposed on the fourth insulating layer 40. The second electrode CNE2 may be connected to the first connection electrode CNE1 through a contact hole passing through the fourth insulating layer 40. A fifth insulating layer 50 may be disposed on the fourth insulating layer 40 and may cover the second connection electrode CNE2. A stack structure of the first insulating layer 10 to the fifth insulating layer 50 is only presented as an embodiment, and additional conductive layers and insulating layers may be further disposed in addition to the first insulating layer 10 to the fifth insulating layer 50.

Each of the fourth insulating layer 40 and the fifth insulating layer 50 may be an organic layer. For example, each of the fourth insulating layer 40 and the fifth insulating layer 50 may include at least one of general polymers (such as benzocyclobutene (BCB), polyimide, hexamethyldisiloxane (HMDSO), polymethylmethacrylate (PMMA), or polystyrene (PS)), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

The light emitting element layer 130 may be disposed on the circuit layer 120. The light emitting element layer 130 may include a light emitting element of the pixel PX described in FIG. 1. For example, the light emitting element may include organic light emitting materials, inorganic light emitting materials, organic-inorganic light emitting materials, quantum dots, quantum rods, micro LEDs, or nano LEDs.

The light emitting element LD may include a first electrode AE (or a pixel electrode), a hole transport region HTR, an emission layer EL, an electron transport region ETR, and a second electrode CE (or a common electrode). The first electrode AE may be disposed on the fifth insulating layer 50. The first electrode AE may be a transflective electrode, a transmissive electrode, or a reflective electrode. The first electrode AE1 may include a reflective layer formed of Ag, Mg, Al, Pt, Pd, Au, Ni, Nd, Ir, Cr, or a compound thereof, and a transparent or semi-transparent electrode layer formed on the reflective layer The transparent or semi-transparent electrode may include at least one of indium tin oxide (ITO), indium zinc oxide (IZO), indium gallium zinc oxide (IGZO), zinc oxide (ZnO), indium oxide (In2O3), and aluminum-doped zinc oxide (AZO). For example, the first electrode AE may include a stack structure of ITO/Ag/ITO.

The pixel defining film PDL may be disposed on the fifth insulating layer 50. According to an embodiment, the pixel defining film PDL may have light absorption properties, and for example, the pixel defining film PDL may be black in color. The pixel defining film PDL may include a black coloring agent. The black coloring agent may include a black dye and a black pigment. The black coloring agent may include carbon black, a metal such as chromium, or an oxide thereof. The pixel defining film PDL may correspond to a light blocking pattern having light blocking properties.

The pixel defining film PDL may cover a portion of the first electrode AE. For example, an opening PDL-OP exposing a portion of the first electrode AE may be defined in the pixel defining film PDL.

The hole transport region HTR may be disposed on the first electrode AE and the pixel defining film PDL. The hole transport region HTR may have a single layer formed of a single material, a single layer formed of different materials, or a multi-layered structure that has multiple layers formed of different materials. For example, the hole transport region HTR may have a single-layer structure formed of a hole injection layer or a hole transport layer, or a single-layer structure formed of a hole injection material and a hole transport material. In an embodiment, the hole transport region HTR may include a hole transport layer, or may further include a hole injection layer.

The emission layer EL may be disposed on the hole transport region HTR. The emission layer EL may include an organic material and/or an inorganic material. The emission layer EL may generate colored light. The emission layer EL may include an organic light emitting material or a quantum dot material.

The electron transport region ETR may be disposed on the emission layer EL and the hole transport region HTR. The electron transport region ETR may have a single layer formed of a single material, a single layer formed of different materials, or a multi-layered structure that has multiple layers formed of different materials. For example, the electron transport region ETR may have a single layer structure of an electron injection layer or an electron transport layer, or may have a single layer structure formed of an electron injection material and an electron transport material. The electron transport region ETR may have a single layer structure formed of different materials, or may include multiple layers sequentially stacked from an emission layer. In an embodiment, the electron transport region ETR may include an electron transport layer or may further include an electron injection layer.

The encapsulation layer 140 may be disposed on the light emitting element layer 130. The encapsulation layer TFE may serve to protect the light emitting element layer 130 from moisture, oxygen, and foreign substances such as dust particles. The encapsulation layer 140 may include an inorganic layer 141, an organic layer 142, and an inorganic layer 143 which are sequentially stacked, but the layers forming the encapsulation layer 140 are not limited thereto.

The inorganic layers 141 and 143 may protect the light emitting element layer 130 from moisture and oxygen, and the organic layer 142 may protect the light emitting element layer 130 from foreign substances such as dust particles. The inorganic layers 141 and 143 may include a silicon nitride layer, a silicon oxynitride layer, a silicon oxide layer, a titanium oxide layer, or an aluminum oxide layer. The organic layer 142 may include an acryl-based organic layer, but the disclosure is not limited thereto.

The input sensor 200 may be disposed on the display panel 100. The input sensor 200 may detect external inputs applied from the outside. The external inputs may be user inputs. The user inputs may include various types of external inputs such as a body part of users, light, heat, pen, or pressure.

The input sensor 200 may be formed on the display panel 100 through a roll-to-roll process. The input sensor 200 may be disposed (e.g., directly disposed) on the display panel 100. As used herein, “a component B is directly disposed on a component A” indicates that a third component is not disposed between the component A and the component B. For example, an adhesive layer may not be disposed between the input sensor 200 and the display panel 100.

The input sensor 200 may be disposed on the display panel 100. The input sensor 200 may include a sensor, an input sensing layer, or an input sensing panel. The input sensor 200 may include a sensor base layer 200-IL1, a first conductive layer 200-CL1, a first insulating layer 200-IL2, a second conductive layer 200-CL2, and a second insulating layer 200-IL3.

The sensor base layer 200-IL1 may be disposed (e.g., directly disposed) on the display panel 100. The sensor base layer 200-IL1 may be an inorganic layer including at least one of silicon nitride, silicon oxynitride, and silicon oxide. In another embodiment, the sensor base layer 200-IL1 may be an organic layer including an epoxy resin, an acrylic resin, or an imide-based resin. The sensor base layer 200-IL1 may have a single-layered structure or may have a multi-layered structure stacked in the third direction DR3.

The first conductive layer 200-CL1 and the second conductive layer 200-CL2 each may have a single-layered structure or may have a multi-layered structure stacked in the third direction DR3. The first conductive layer 200-CL1 and the second conductive layer 200-CL2 may include conductive lines that define a sensing electrode in the form of a mesh. The conductive lines may non-overlap the opening PDL-OP and may overlap the pixel defining film PDL in a plan view.

The first conductive layer 200-CL1 and the second conductive layer 200-CL2 having a single-layered structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). The transparent conductive layer may include a conductive polymer such as PEDOT, a metal nanowire, graphene, and the like.

The first conductive layer 200-CL1 and the second conductive layer 200-CL2 having a multi-layered structure may include metal layers which are sequentially staked. The metal layers may have a three-layer structure of, for example, titanium/aluminum/titanium. The first conductive layer 200-CL1 and the second conductive layer 200-CL2 may include at least one metal layer and at least one transparent conductive layer.

The first insulating layer 200-IL2 may be disposed between the first conductive layer 200-CL1 and the second conductive layer 200-CL2. The first insulating layer 200-IL2 may cover the first conductive layer 200-CL1 and may be disposed on the sensor base layer 200-IL1. The second insulating layer 200-IL3 may be disposed on the second conductive layer 200-CL2. The second insulating layer 200-IL3 may cover the second conductive layer 200-CL2 and may be disposed on the first insulating layer 200-IL2.

The first insulating layer 200-IL2 and the second insulating layer 200-IL3 may each independently include an inorganic film or an organic film. The inorganic film may include at least one of aluminum oxide, titanium oxide, silicon oxide, silicon nitride, silicon oxynitride, zirconium oxide, and hafnium oxide. The organic film may include at least one of an acryl-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

The anti-reflector 300 may be disposed on the input sensor 200. The anti-reflector 300 may reduce reflectivity of external light. The anti-reflector 300 may be disposed (e.g., directly disposed) on the input sensor 200 through a roll-to-roll process. The anti-reflector 300 may include a light blocking pattern 310, a color filter 320, and a planarization layer 330.

A material constituting the light blocking pattern 310 is not particularly limited as long as the material absorbs light. The light blocking pattern 310 may be a layer which is black in color, and in an embodiment, the light blocking pattern 310 may include a black coloring agent. The black coloring agent may include a black dye and a black pigment. The black coloring agent may include carbon black, a metal such as chromium, or an oxide thereof. The light blocking pattern 310 may prevent reflection of external light by the first conductive pattern 200-CL1 and the second conductive pattern 200-CL2.

The color filter 320 may overlap at least the pixel region PXA in a plan view. The color filter 320 may further overlap the peripheral region NPXA in a plan view. A portion of the color filter 320 may be disposed on the light blocking pattern 310. The color filter 320 may transmit the light generated from the light emitting element LD and block some wavelength bands of external light. Accordingly, the color filter 320 may reduce the reflection of external light by the first electrode AE or the second electrode CE. The color filter may include a first color filter, a second color filter, and a third color filter, which correspond to a first color pixel, a second color pixel, and a third color pixel.

The planarization layer 330 may cover the light blocking pattern 310 and the color filter 320. The planarization layer 330 may include an organic material, and the planarization layer 330 may provide a flat upper surface.

The anti-reflector 300 may reduce reflectance of light incident from the outside. The anti-reflector 300 may include a retarder and/or a polarizer. The anti-reflector 300 may include at least one polarizing film.

Although not shown in FIG. 2, the display device DD may further include a window (not shown). The window (not shown) may be disposed on the anti-reflector 300.

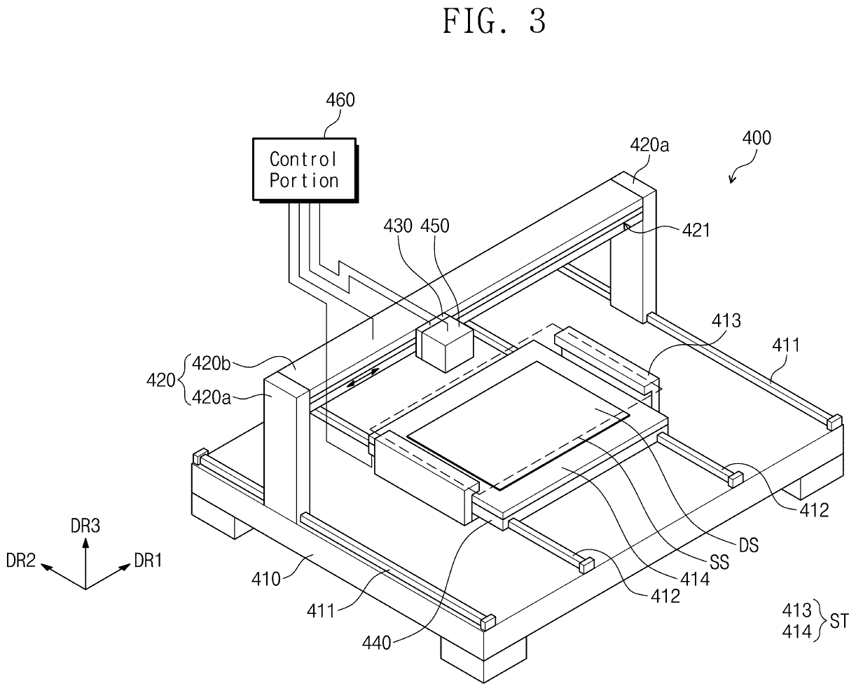

FIG. 3 is a perspective view schematically showing a device for manufacturing a display device according to an embodiment of the disclosure.

Referring to FIG. 3, a device for manufacturing a display device 400 may include a support portion 410, a first moving portion 420, a second moving portion 430, a third moving portion 440, a laser irradiation unit (or laser irradiation portion) 450, and a control portion 460. The device for manufacturing a display device 400 may include a stage ST disposed on the support portion 410, a display substrate SS placed on the stage ST, and a donor substrate DS facing the display substrate SS.

The support portion 410 may have a plane defined by the first direction DR1 and the second direction DR2 intersecting the first direction DR1.

The first moving portion 420, the second moving portion 430, the third moving portion 440, and the laser irradiation unit 450 may be disposed on the support portion 410.

The stage ST may form a work area in a manufacturing process of the display device DD (see FIG. 1). The stage ST may include a first fixing portion 413 and a second fixing portion 414. The display substrate SS may be provided on the first fixing portion 413, and the donor substrate DS may be provided on the second fixing portion 414. The display substrate SS may be a portion of the display device DD (FIG. 1) under process of manufacture, and may be an object to which a transfer layer OL of the donor substrate DS, which will be described below, is transferred.

The display substrate SS may be placed on the first fixing portion 413, and the donor substrate DS may be placed on the second fixing portion 414. The second fixing portion 414 may have a plane defined by the first direction DR1 and the second direction DR2. Although not shown, the stage ST may further include an alignment mark for aligning the display substrate SS and the donor substrate DS.

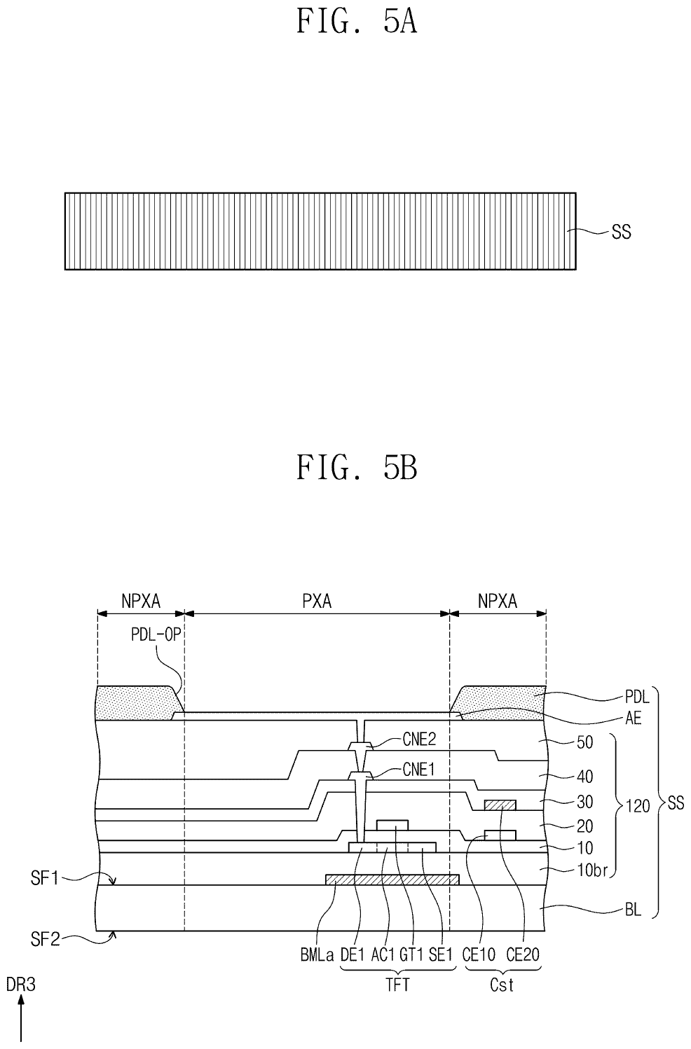

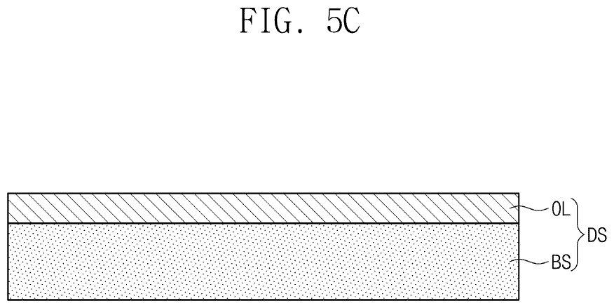

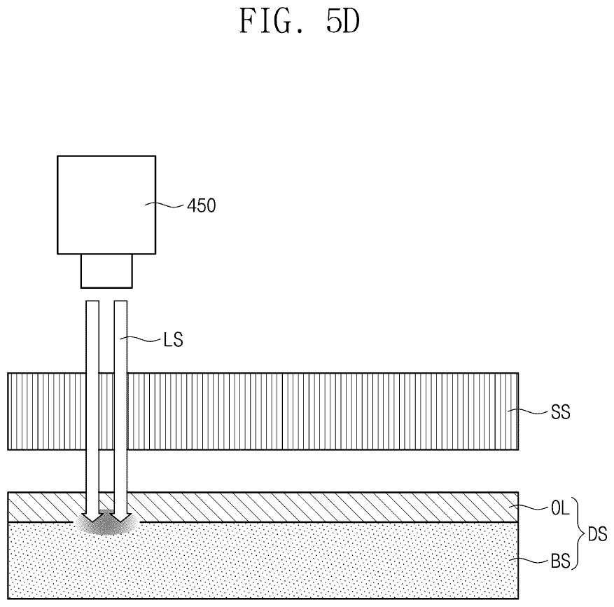

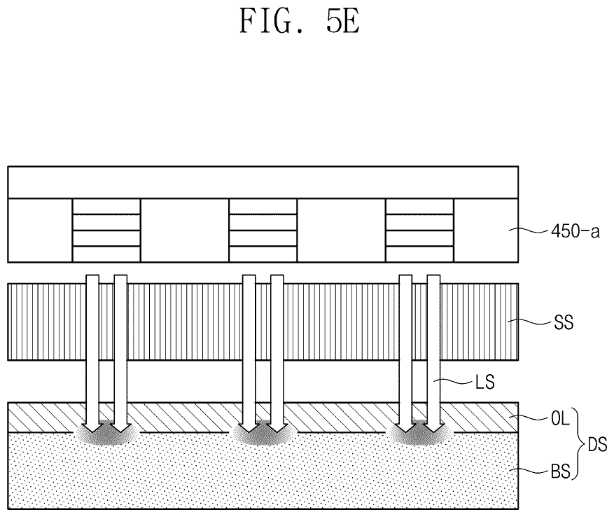

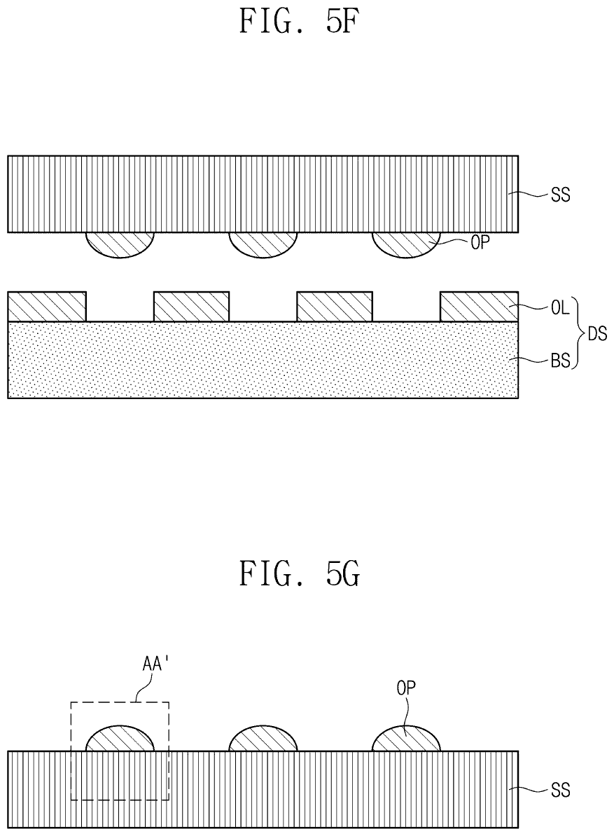

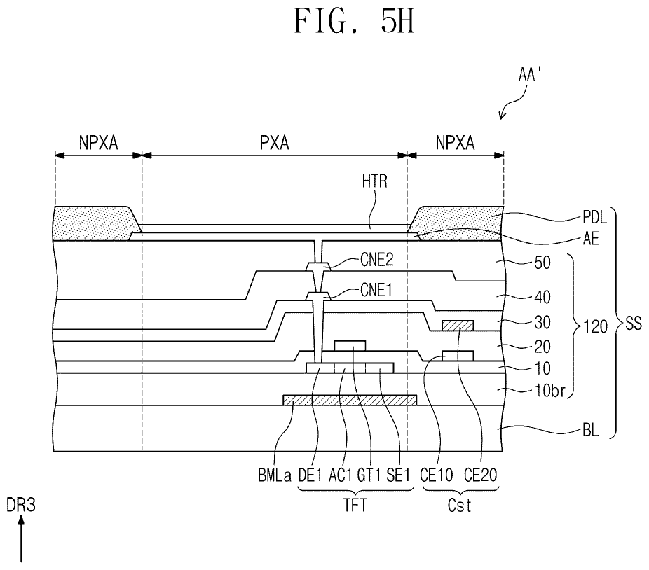

The donor substrate DS may be disposed on the second fixing portion 414 to overlap the display substrate SS in a plan view. The donor substrate DS may be spaced apart from the display substrate SS. The donor substrate DS may include a base layer BS (FIG. 5C) and a transfer layer OL (FIG. 5C) disposed on the base layer BS (FIG. 5C). The donor substrate DS will be described in detail below.

In an embodiment, the device for manufacturing a display device 400 may include a first guide portion 411 disposed on the support portion 410. The first guide portion 411 may extend in the second direction DR2. The first guide portions 411 may be provided in plurality, and the first guide portions 411 may be spaced apart from each other in the first direction DR1. For example, as shown in FIG. 3, two first guide portions 411 may be provided and spaced apart from each other with the stage ST interposed between the two first guide portions 411. An extension length of each of the first guide portions 411 in the second direction DR2 may be greater than at least a length of an edge of the display substrate SS in the second direction DR2. The first guide portion 411 may guide the first moving portion 420 to perform a linear motion along an extending direction of the first guide portion 411. The first guide portion 411 may include, for example, a linear motion rail.

The first moving portion 420 may linearly move back and forth in the second direction DR2. In an embodiment, the first moving portion 420 may include column members 420a and horizontal members 420b. The column members 420a of the first moving portion 420 may extend in a third direction DR3 intersecting each of the first direction DR1 and the second direction DR2. The column members 420a may be provided in plurality. For example, two column members 420a may be provided, and the two column members 420a may be disposed on sides of the stage ST. The column members 420a may each move along the extension direction of the first guide portions 411, for example, the second direction DR2. In an embodiment, the column members 420a may manually perform a linear motion or automatically perform a linear motion, using a motor cylinder or the like. For example, the column members 420a may include a linear motion block that moves along the linear motion rail to automatically perform a linear motion.

The horizontal member 420b of the first moving portion 420 may be disposed between the column members 420a and connect the column members 420a. The horizontal member 420b may extend in the first direction DR1 between the column members 420a. Ends of the horizontal member 420b may be connected to an upper portion of each of the column members 420a. However, the disclosure is not limited to the structures and shapes of the column members 420a and the horizontal member 420b shown in FIG. 3. Any structure and shape in which the first moving portion 420 linearly moves back and forth in the second direction DR2 may be adoptable without limitation.

The second moving portion 430 may perform a linear motion in the first direction DR1. The second moving portion 430 may be movably connected to a side of the horizontal member 420b of the first moving portion 420. The horizontal member 420b of the first moving portion 420 may include a first groove portion 421 extending in the extending direction of the horizontal member 420b, for example the first direction DR1. The second moving portion 430 may be disposed on a side of the horizontal member 420b where the first groove portion 421 is disposed. The first groove portion 421 may guide the second moving portion 430 to linearly move back and forth along the extending direction of the first groove portion 421. The second moving portion 430 may linearly move back and forth in the first direction DR1 along the first groove portion 421. The second moving portion 430 may include a linear motor or the like.

The laser irradiation unit 450 may perform irradiation of a laser beam in a direction. For example, in the embodiment shown in FIG. 3, a laser beam emitted from the laser irradiation unit 450 may travel in the third direction DR3.

The laser irradiation unit 450 may be spaced apart from the donor substrate DS with the display substrate SS between the laser irradiation unit 450 and the donor substrate DS. The laser irradiation unit 450 may irradiate the display substrate SS disposed to overlap the donor substrate DS with a laser. The laser irradiation unit 450 may irradiate the donor substrate DS with a laser on (or through) the display substrate SS.

Although not shown, the laser irradiation unit 450 may include a light source (not shown) generating a laser, and an optical system (not shown) disposed in a traveling path of the laser. The light source (not shown) may generate a laser, and a solid riser such as a ruby laser or a gas laser such as a helium-neon laser may be used. The optical system (not shown) may receive a laser generated from the light source (not shown) and adjust irradiation conditions of the laser. For example, the shape and intensity of the laser, the size of a spot, an irradiation angle, and the number of times of irradiation may be finely adjusted. The optical system (not shown) may include a homogenizer that homogenizes the shape of a laser in order to mold the shape of the laser into a desired shape, and may include a mirror that changes an angle of the laser. The optical system (not shown) may include a combination of various lens groups such as a condensing lens or a polarizer.

In an embodiment, the laser irradiation unit 450 may include a vertical cavity surface light emitting laser (VCSEL).

The laser provided from the laser irradiation unit 450 may have a wavelength capable of transmitting without denaturing an organic material included in the transfer layer OL. For example, the laser may have a wavelength in a range of about 0.8 μm to about 20 μm. In case that the wavelength of the laser satisfies the ranges described above, the organic material included in the transfer layer OL may be denatured to the minimum, and the base layer BS may readily absorb the laser as well to allow efficient transfer.

The laser irradiation unit 450 may be disposed on a side of the second moving portion 430. The laser irradiation unit 450 may move along with the movement of the first moving portion 420 and the second moving portion 430. For example, the first moving portion 420 and the second moving portion 430 may move the laser irradiation unit 450 in a direction intersecting the traveling direction of the laser. For example, the first moving portion 420 and the second moving portion 430 may move the laser irradiation unit 150 in the first direction DR1 and the second direction DR2. The moving range of the laser irradiation unit 450 may cover a region of the support 410. Accordingly, the laser irradiation unit 450 may irradiate an entire surface of a display substrate SS on the support 410 with the laser beam.

The control portion 460 may be electrically connected to the first moving portion 420 and the second moving portion 430, and may control the position and movement of each of the first moving portion 420 and the second moving portion 430. The control portion 460 may be electrically connected to the laser irradiation unit 450 and may control irradiation time period, output, and the like of the laser irradiation unit 450.

In an embodiment, the device for manufacturing a display device 400 may include a second guide portion 412 disposed on the support portion 410. The second guide portion 412 may extend in the second direction DR2. The second guide portions 412 may be provided in plurality, and the second guide portions 412 may be spaced apart from each other in the first direction DR1. The second guide portion 412 may guide the third moving portion 440 to perform a linear motion along the extending direction of the second guide portion 412. The second guide portion 412 may include a linear motion rail.

The third moving portion 440 may linearly move back and forth in the second direction DR2. The third moving portion 440 may be movably connected to the second guide portion 412. The third moving portion 440 may move along the extension direction of the second guide portion 412, for example, the second direction DR2. In an embodiment, the third moving portion 440 may manually perform a linear motion or automatically perform a linear motion, using a motor cylinder or the like. For example, the third moving portion 440 may include a linear motion block that moves along the linear motion rail to automatically perform a linear motion.

The third moving portion 440 may be configured such that the donor substrate DS on the second fixing portion 414 relatively moves with respect to the display substrate SS. The second fixing portion 414 may be disposed on the third moving portion 440, and as the third moving portion 440 moves, the second fixing portion 414 may also move along. The display substrate SS may be fixed by the first fixing portion 413 disposed on the support portion 410. The first fixing portion 413 may include a chuck capable of fixing the donor substrate DS.

Although FIG. 3 schematically illustrate an embodiment in which the display substrate SS is provided on the first fixing portion 413, and the donor substrate DS is provided on the second fixing portion 414, the disclosure is limited to thereto. In another embodiment, the donor substrate DS may be provided on the first fixing portion 413, and the display substrate SS may be provided on the second fixing portion 414. The laser irradiation unit 450 may be disposed below the display substrate SS, and may irradiate the donor substrate DS with a laser from below the display substrate SS. The second fixing portion 414 on which the display substrate SS is placed may be made of a material having high transmittance for light emitted from the laser irradiation unit 450.

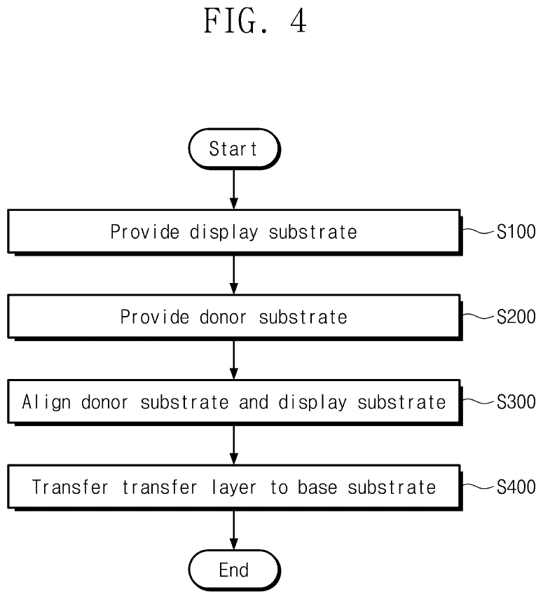

FIG. 4 is a flowchart showing a method for manufacturing a display device according to an embodiment of the disclosure. FIGS. 5A to 5I are views showing some processes in a method for manufacturing a display device according to an embodiment of the disclosure. FIG. 5H is a schematic enlarged cross-sectional view of a portion corresponding to AA′ in FIG. 5G. Hereinafter, in describing the method for manufacturing a display device according to an embodiment with reference to FIGS. 5A to 5I, the same reference numerals are given to components that are the same as the components described above, and detailed descriptions thereof will not be provided.

Referring to FIG. 4, the method of manufacturing a display device according to an embodiment may include providing a display substrate (S100), providing a donor substrate (S200), aligning the donor substrate and the display substrate (S300), and transferring a transfer layer to the base substrate (S400).

FIGS. 5A and 5B are views showing processes of providing a display substrate SS. Referring to FIGS. 5A and 5B, the display substrate SS may include all substrates designed to form an organic pattern through a laser thermal transfer method. The display substrate SS may be a substrate to which a transfer layer OL of a donor substrate DS is transferred in the process of transferring (S400), which will be described below. For example, the display substrate SS may be a portion of the display device DD (FIG. 1) under process of manufacture, and may be a substrate in a state before the light emitting element LD (FIG. 2) is formed. For example, the display substrate SS may include a base substrate BL, and a circuit layer 120 disposed on the base substrate BL.

A pixel region PXA and a peripheral region NPXA adjacent to the pixel region PXA may be defined on the base substrate BL. The pixel region PXA may be a region divided by the pixel defining film PDL. The peripheral region NPXA may be a region between neighboring pixel regions PXA and may correspond to the pixel defining film PDL. In an embodiment, the pixel region PXA may correspond to a region in which the transfer layer OL is transferred from the donor substrate DS.

The base substrate BL may include a first surface SF1 and a second surface SF2, which are opposite to each other with respect to the third direction DR3. The first surface SF1 of the base substrate BL may be a portion facing the donor substrate DS in the process of transferring (S400), which will be described below. The second surface SF2 may face the first surface SFI and may be a portion on which a laser is incident.

The base substrate BL may include a material having high transmittance for a light used in the process of transferring (S400), which will be described below. The base substrate BL may include a material having high transmittance for the laser emitted from the above described laser irradiation unit 400 (see FIG. 3). For example, the base substrate BL may include a material having high light transmittance for light having a central wavelength in a range of about 0.8 μm to about 20 μm. In an embodiment, the base substrate BL may include at least one of silicon (Si), calcium fluoride (CaF₂), gallium arsenide (GaAs), and germanium (Ge).

The display substrate SS may further include a first electrode AE disposed on the first surface SF1 of the base substrate BL. The first electrode AE may be disposed on the circuit layer 120. The first electrode AE may be disposed to overlap the pixel region PXA in a plan view. The display substrate SS may further include a pixel defining film PDL disposed on the first electrode AE of the base substrate BL. A pixel opening PDL-OP exposing a portion of the first electrode AE may be defined in the pixel defining film PDL.

FIG. 5C is a view showing a process of providing a donor substrate DS. Referring to FIG. 5C, the donor substrate DS may include a base layer BS, and a transfer layer OL disposed on the base layer BS. The base layer BS may have bearing capacity sufficient to support the transfer layer OL, and may have a high absorption rate with respect to a wavelength of the light. The base layer BS may include a material having a high absorption rate for the laser emitted from the above described laser irradiation unit 450 and having photothermal conversion properties.

The base layer BS may include a photothermal conversion material. The base layer BS may include a material having excellent photothermal conversion properties. In an embodiment, the base layer BS may include at least one of glass, aluminum oxide (Al₂O₃), and aluminum oxynitride (AlON). For example, the base layer BS may be formed of at least one of glass, aluminum oxide (Al₂O₃), and aluminum oxynitride (AlON). The base layer BS may include at least one of glass, aluminum oxide (Al₂O₃), and aluminum oxynitride (AlON), and may thus have a high absorption rate for the laser provided in the process of transferring (S400) (FIG. 4), and accordingly, even in case that a separate light conversion layer is not provided, the base layer BS may absorb the laser and transfer thermal energy to the transfer layer OL, resulting in a simplified structure of the donor substrate DS. The simplified structure of the donor substrate DS may reduce manufacturing costs of a display device, and provide benefits for manufacturing a large area display device.

The transfer layer OL may be disposed on the base layer BS. In an embodiment, the transfer layer OL may be disposed (e.g., directly disposed) on the base layer BS. An upper surface of the base layer BS may contact a lower surface of the transfer layer OL. A separate layer may not be disposed between the base layer BS and the transfer layer OL. In an embodiment, the donor substrate DS may be formed of the base layer BS, and the transfer layer OL disposed on the base layer BS.

The transfer layer OL may include an organic material. The organic material included in the transfer layer OL may be used to form a functional layer of the light emitting element LD (FIG. 2) on the display substrate SS. The light emitting element LD (FIG. 2) of the display device DD (FIG. 2) may include at least one functional layer disposed between the first electrode AE (FIG. 2) and the second electrode CE (FIG. 2), and at least one functional layer may be formed from the transfer layer OL. For example, the light emitting element LD (FIG. 2) may include a hole transport region HTR (FIG. 2), an emission layer EL (FIG. 2), and an electron transport region ETR (FIG. 2), and at least one of the hole transport region HTR (FIG. 2), the emission layer EL (FIG. 2), and the electron transport region ETR (FIG. 2) may be formed from the transfer layer OL.

The transfer layer OL may be a layer that may be vaporized or sublimated by heat generated from the base layer BS, and may include at least one of a hole transport material, a light emitting material, and a hole injection material. For example, the transfer layer OL and at least one of the hole transport region HTR (FIG. 2), the emission layer EL (FIG. 2), and the electron transport region ETR (FIG. 2) may include a same material.

FIGS. 5D to 5G are views showing a process of aligning a display substrate and a donor substrate (S300) and a process of transferring a transfer layer to a base substrate (S400).

Referring to FIGS. 5B, 5D, and 5E together, the aligning of the display substrate SS and the donor substrate DS (S300) may be performed. The donor substrate DS and the display substrate SS may be aligned such that the transfer layer OL of the donor substrate DS faces the display substrate SS. For example, the display substrate SS and the donor substrate DS may be aligned such that the transfer layer OL of the donor substrate DS faces the first electrode AE of the display substrate SS. The above described third moving portion 440 (see FIG. 3) may be used to align the display substrate SS and the donor substrate DS.

After the aligning of the display substrate SS and the donor substrate DS (S300), irradiating the donor substrate DS with a laser LS on the display substrate SS may be performed. The irradiation of the laser LS may be performed on the second surface SF2 of the base substrate BL to transfer the transfer layer OL onto the first electrode AE.

Referring to FIG. 5D, one laser irradiation unit 450 may be used in the irradiating of the donor substrate DS with the laser LS. The laser irradiation unit 450 may irradiate the donor substrate DS with the laser LS on a side of the display substrate SS spaced apart from the donor substrate DS. The laser irradiation unit 450 may have a resolution of a pixel unit or smaller to facilitate forming patterns corresponding to the pixel region PXA (FIG. 5B).

The laser irradiation unit 450 may be spaced apart from the donor substrate DS with the display substrate SS interposed between the laser irradiation unit 450 and the donor substrate DS. The laser irradiation unit 450 may irradiate the donor substrate DS with the laser LS while moving on the display substrate SS.

The laser irradiation unit 450 may locally irradiate only a region where the transfer layer OL is supposed to be transferred with the laser LS on the display substrate SS. Portions of the display substrate SS where the transferred organic pattern OP (FIG. 5F) is supposed to be formed may be irradiated with the laser LS. For example, the laser irradiation unit 450 may irradiate only a portion of the display substrate SS overlapping the pixel region PXA (FIG. 5B) in a plan view with the laser LS.

The laser LS may pass through the display substrate SS and the transfer layer OL to reach the base layer BS. In case that the laser LS is incident on the base layer BS, the base layer BS may partially absorb the laser LS and convert a portion the absorbed light into heat. A portion of the donor substrate DS overlapping the pixel region PXA (FIG. 5B) in a plan view may be irradiated with a laser, and heat may be selectively generated in a portion of the base layer BS overlapping the pixel region PXA in a plan view. The heat generated from the base layer BS may be transferred to the transfer layer OL, and the transfer layer OL in the region irradiated with the laser LS may be vaporized or sublimated and transferred to the display substrate SS. An organic material included in the transfer layer OL separated from the donor substrate DS may be transferred onto the first electrode AE.

The laser LS provided from the laser irradiation unit 450 may have a wavelength in an infrared region. For example, the laser LS may have a wavelength in a range of about 0.8 μm to about 20 μm. In case that the wavelength of the laser LS satisfies the ranges described above, the organic material included in the transfer layer OL may be denatured to the minimum, and the base layer BS may readily absorb the laser as well to allow efficient transfer.

Referring to FIG. 5E, a laser irradiation unit 450-a may be a vertical cavity surface light emitting laser. The laser irradiation unit 450-a may be a laser device designed to perform irradiation of the laser LS according to an interval between the pixel regions PXA (FIG. 5B). For example, the laser irradiation unit 450-a may concurrently perform irradiation of the laser LS according to an interval between the pixel regions PXA (FIG. 5B). The interval may vary depending on the use of the light emitting element LD. For example, in case that the light emitting element LD is used as a backlight light emitting element, the of pixel regions PXA (FIG. 5B) may each have one interval, and in the case of light emitting elements using different organic materials for red, green, and blue colors, a single pixel region PXA (FIG. 5B) may have one interval.

In an embodiment, the transferring of a transfer layer to a base substrate (S400) may be performed in a condition that the display substrate SS and the donor substrate DS are spaced apart from each other by a distance. For example, irradiation of the laser LS may be performed in a condition that the transfer layer OL of the donor substrate DS is spaced apart from the base substrate BL of the display substrate SS by an interval. As the transfer is performed while the display substrate SS and the donor substrate DS are spaced apart from each other by a distance, a process of laminating the donor substrate DS and the display substrate SS may not be required, and undesirable attachment or detachment of the transfer layer OL, which may take place in the process of separating the donor substrate DS and the display substrate SS may be prevented. However, the disclosure is not limited thereto, and the method for manufacturing a display device of an embodiment may further include laminating the donor substrate DS from the display substrate SS, prior to the transferring of a transfer layer to a base substrate (S400). For example, unlike what is shown in FIGS. 5D and 5E, the donor substrate DS may be irradiated with the laser LS in a condition that the donor substrate DS is in contact with the display substrate SS, and after the process of transferring, separating the donor substrate DS and the display substrate SS may be performed.

Referring to FIGS. 5F and 5G, in the transferring of a transfer layer to a base substrate (S400), the transfer layer OL may be transferred onto the first electrode AE to form an organic pattern OP. Of the transfer layer OL, a portion which is not irradiated with the laser LS (FIGS. 5D and 5E) may remain on the donor substrate DS.

Referring to FIGS. 5G and 5H, the organic pattern OP may correspond to the hole transport region HTR. However, the disclosure is not limited thereto, and the organic pattern OP may correspond to the emission layer EL or the electron transport region ETR.

Referring to FIGS. 5H and 5I, the transferring of a transfer layer to a display substrate (S400) may include transferring the hole transport region HTR onto the first electrode AE, transferring the emission layer EL onto the hole transport region HTR, and transferring the electron transport region ETR onto the emission layer EL. As shown in FIG. 5I, after the transferring of the hole transport region HTR onto the first electrode AE, the transferring of the emission layer EL and the transferring of the electron transport region ETR may be sequentially performed. Another donor substrate on which a first transfer layer including a light emitting material is formed may be prepared on the base layer BS (FIG. 5C) and the display substrate SS on which the hole transport region HTR is formed may be rearranged, and irradiation of the laser LS may selectively be performed to transfer the first transfer layer onto the hole transport region HTR. Thereafter, another donor substrate on which a second transfer layer including an electron transport material is formed may be prepared on the base layer BS (FIG. 5C) and the display substrate SS on which the emission layer EL is formed may be rearranged, and irradiation of the laser LS may selectively be performed to transfer the second transfer layer onto the emission layer EL. However, the disclosure is not limited thereto, and in case that the transfer layer OL includes a hole transport material, a light emitting material, and an electron transport material all together, the hole transport region HTR, the emission layer EL, and the electron transport region ETR may be collectively transferred onto the first electrode AE.

Both the typical methods of LITI and LIPS are characterized in that a laser beam is emitted from a back side of a donor substrate including an organic layer, and accordingly, the donor substrate may be required to have high transmittance for a light source, and additionally introducing a photothermal conversion layer for converting energy of the light into thermal energy may be inevitable. As a result, the introduction of an additional structure may cause a rise in manufacturing costs of the donor substrate, and in case that a light source is emitted from the back side of the complicated donor substrate, scattering at an interface may cause light loss.

According to an embodiment of the disclosure, the light having high transmittance for an organic material may be emitted from the back side of the display substrate to allow patterning in pixel units without concern over deterioration of a transfer layer of the donor substrate, and a donor substrate whose configuration is simplified by designing the base layer itself to have photothermal conversion properties may be used. Accordingly, the manufacturing costs of the donor substrate may be prevented from rising, and the light loss caused by the scattering at an interface between layers in case that the light source is incident from the back side of the typical donor substrate may be prevented. As the light source is emitted from the back side of the display substrate, absorption of the light source by the base layer may be minimized in the process of transferring to prevent deterioration of the base layer.

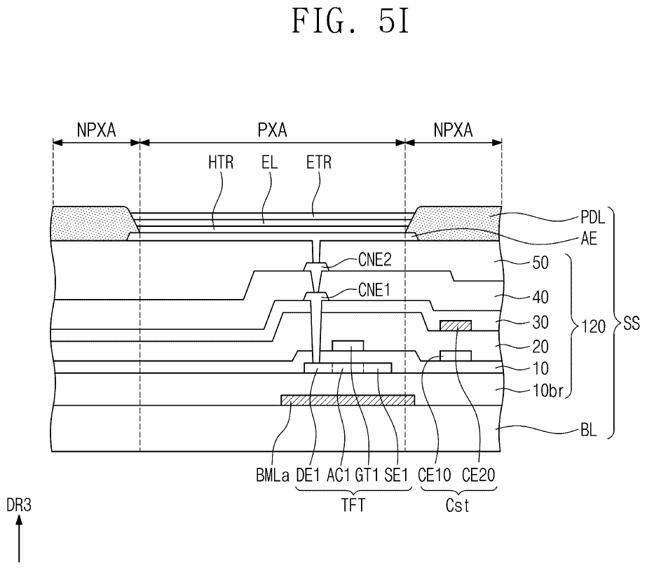

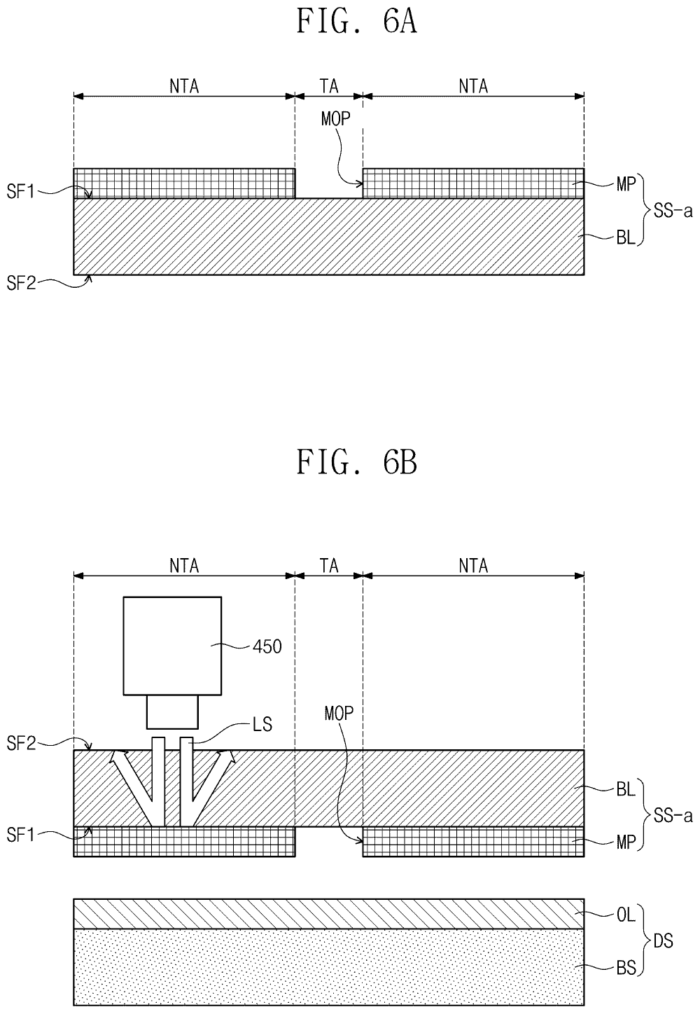

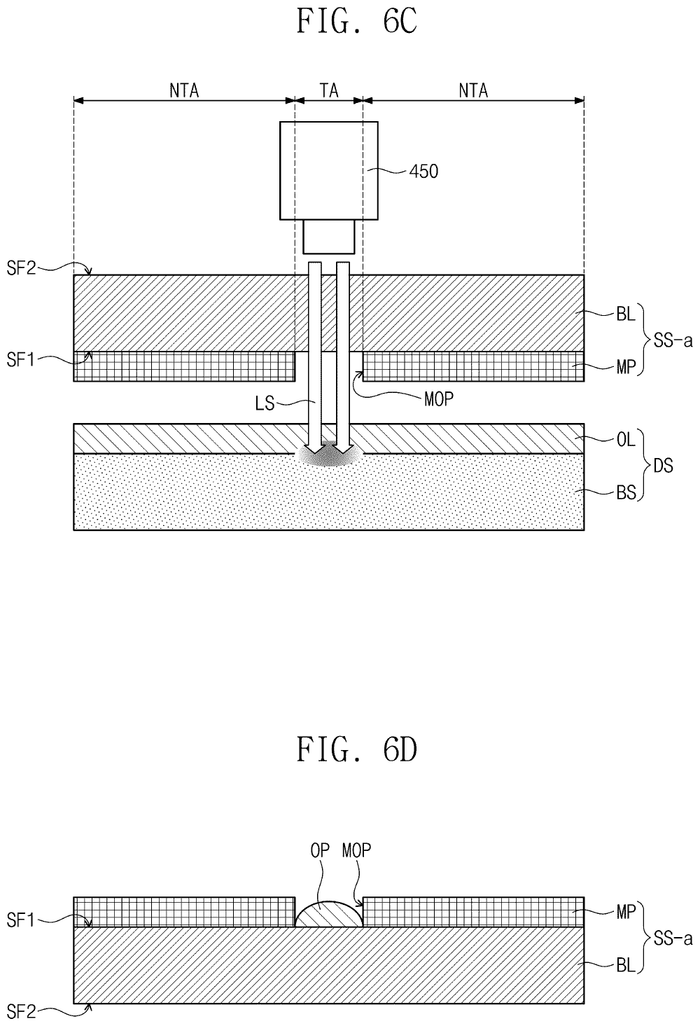

FIGS. 6A to 6D are schematic cross-sectional views showing some processes in the method for manufacturing a display device according to an embodiment of the disclosure. Hereinafter, in describing the method for manufacturing a display device according to an embodiment with reference to FIGS. 6A to 6D, the same reference numerals are given to components that are the same as the components described above, and detailed descriptions thereof will not be provided.

The method for manufacturing a display device shown in FIGS. 6A to 6D may differ from the method for manufacturing a display device described with reference to FIGS. 5A to 5I in that the display substrate SS provided in the process of transferring further may include a metal pattern MP.

Referring to FIG. 6A, a display substrate SS-a may further include a metal pattern MP disposed on the base substrate BL. The metal pattern MP may be a film having an appropriate reflectance for the laser and may reflect the laser emitted to the display substrate SS-a. The metal pattern MP may be disposed on a first surface SF1 of the base substrate BL. The first surface SF1 of the base substrate BL may be a portion facing the donor substrate DS in the process of transferring, which will be described below. The second surface SF2 may face the first surface SF1 and may be a portion on which a laser is incident. For convenience of description, FIGS. 6A to 6D show that no separate layer is disposed between the base substrate BL and the metal pattern MP, but the disclosure is not limited thereto. As shown in FIG. 5B, the display substrate SS-a may include at least one of a circuit layer 120, a first electrode AE, and a pixel defining film PDL, which are disposed on the base substrate BL. The metal pattern MP may be disposed on the circuit layer 120 or may be disposed on the pixel defining film PDL.

An opening MOP may be defined in the metal pattern MP. Unlike what is shown in FIG. 6A, the opening MOP may be provided in plurality. Of the display substrate SS, a portion in which the metal pattern MP is formed may be defined as a reflection region NTA, and a portion in which the metal pattern MP is not formed, for example, the portion in which the opening MOP is defined, may be defined as a transmission region TA. The transmission region TA may correspond to a portion transferred to the transfer layer OL by the donor substrate DS. The reflection region NTA may correspond to a non-transfer region. In an embodiment, the opening MOP may overlap at least the pixel region PXA (FIG. 5B) in a plan view.

The metal pattern MP may include a metal having a high reflectance with respect to a light. In an embodiment, the metal pattern MP may include at least one of gold (Au), silver (Ag), tungsten (W), and titanium (Ti). For example, the metal pattern MP may be formed of at least one of gold (Au), silver (Ag), tungsten (W), and titanium (Ti).

The base layer BS may absorb laser incident on a transmission region of the display substrate SS and convert the laser into heat. The transfer layer OL may be disposed on the base layer BS. The transfer layer OL may be formed in both the transmission region and the non-transmission region.

Referring to FIGS. 6B and 6C, aligning the display substrate SS-a and the donor substrate DS may be performed. The donor substrate DS and the display substrate SS may be aligned such that the transfer layer OL of the donor substrate DS faces the display substrate SS-a. For example, the display substrate SS-a and the donor substrate DS may be aligned such that the transfer layer OL of the donor substrate DS faces the metal pattern MP of the display substrate SS-a.

After the aligning of the display substrate SS-a and the donor substrate DS, irradiating the donor substrate DS with a laser LS on the display substrate SS-a may be performed. The irradiation of the laser LS may be performed on the second surface SF2 of the base substrate BL to transfer the transfer layer OL to the display substrate SS-a.

An entire surface of the display substrate SS-a may be irradiated with the laser LS. For example, the laser irradiation unit 450 may continuously move on the display substrate SS-a and irradiate the donor substrate DS with the laser LS. Accordingly, the entire second surface SF2 of the base substrate BL may be irradiated with the laser LS.

Referring to FIGS. 6B to 6D, a portion of the base layer BS, which nonoverlaps the metal pattern MP in a plan view may be irradiated with a laser, and a portion of the base layer BS, which overlaps the metal pattern MP in a plan view may not be irradiated with a laser. As shown in FIG. 6B, the laser LS incident on the reflection region NTA through the second surface SF2 of the base substrate BL may be reflected by the metal pattern MP. The laser LS incident on the transmission region TA through the second surface SF2 of the base substrate BL may be incident on the donor substrate DS. The laser LS incident on the transmission region TA may pass through the transfer layer OL and be transmitted to the base layer BS. A portion of the base layer BS, which overlaps the transmission region TA in a plan view may absorb a laser LS and convert a portion of the laser into thermal energy. The transfer layer OL may be vaporized or sublimated by the generated heat and transferred onto the display substrate SS-a. The transfer layer OL may be transferred through an opening MOP corresponding to the transmission region TA. The transfer layer OL of the donor substrate DS may include a first portion overlapping the metal pattern MP and a second portion nonoverlapping the metal pattern MP in a plan view, and after irradiation of the laser LS, the second portion of the transfer layer OL may be transferred onto the base substrate BL, and the first portion of the transfer layer OL may remain on the base layer BS without being transferred. An organic material included in the transfer layer OL may be vaporized or sublimated by heat generated by irradiation of the laser LS and be subjected to deposition in the opening MOP to form the organic pattern OP.

Only a portion of the donor substrate DS, which corresponds to the transmission region TA may be irradiated with the laser LS. Accordingly, with no need of scanning the laser LS while aligning the laser to correspond to a transfer region, even in case that the laser LS is collectively transmitted on the display substrate SS-a, only a portion corresponding to the transfer region may be selectively transferred, resulting in improved process efficiency. By simply transmitting the laser on the second surface SF2 of the base substrate BL without separating specific regions, the transfer layer OL may be transferred to the transmission region TA corresponding to the transfer region, resulting in reduced process time for manufacturing a display device. For example, an organic pattern may be collectively formed in the transfer region through a single process, and the time required for manufacturing may thus be reduced to increase process efficiency. According to an embodiment of the disclosure, even in case that the entire display substrate SS-a is transmitted, an organic pattern may be formed in a target transfer region, and the process efficiency may thus be increased.

The metal pattern MP may serve as an electrode in the display device DD (FIG. 1) which is finally manufactured after the process of transferring. For example, the metal pattern MP may serve as a second electrode CE of the light emitting element LD. However, the disclosure is not limited thereto, and the metal pattern MP may be removed from the display substrate SS after the process of transferring.

According to an embodiment of the disclosure, a device for manufacturing a display device capable of patterning an organic material on a donor substrate without concern over denaturation of the organic material in a region irradiated with a light source and improving cost efficiency, using a donor substrate having a simplified constitution, and a method for manufacturing the display device is provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method for manufacturing a display device, the method comprising:
providing a display substrate including a base substrate having a pixel region and including a first surface and a second surface, which are placed opposite to each other;
providing a donor substrate including a base layer and a transfer layer disposed on the base layer and including an organic material such that the transfer layer is spaced apart from the base substrate by a distance;
aligning the donor substrate and the display substrate such that the transfer layer faces the first surface of the base substrate; and
transferring the transfer layer to the display substrate by irradiating a laser toward the donor substrate on the second surface of the base substrate.

2. The method of claim 1, wherein the laser has a wavelength in a range of about 0.8 μm to about 20 μm.

3. The method of claim 1, wherein the base layer comprises at least one of glass, aluminum oxide (Al₂O₃), and aluminum oxynitride (AlON).

4. The method of claim 1, wherein the base layer comprises a photothermal conversion material.

5. The method of claim 1, wherein the transfer layer is directly disposed on the base layer.

6. The method of claim 1, wherein the base substrate comprises at least one of silicon (Si), calcium fluoride (CaF₂), gallium arsenide (GaAs), and germanium (Ge).

7. The method of claim 1, wherein the transfer layer comprises at least one of a hole transport material, a light emitting material, and an electron transport material.

8. The method of claim 1, wherein the display substrate further includes a metal pattern disposed on the base substrate and having an opening corresponding to the pixel region.

9. The method of claim 8, wherein the metal pattern comprises at least one of gold (Au), silver (Ag), tungsten (W), and titanium (Ti).

10. The method of claim 8, wherein after the transferring of the transfer layer to the display substrate, an organic pattern is formed in the opening.

11. The method of claim 8, further comprising:
removing the metal pattern after the transferring of the transfer layer to the display substrate.

12. The method of claim 1, wherein
the display substrate further includes:
a first electrode disposed on the base substrate; and
a pixel defining film disposed on the first electrode and having a pixel opening overlapping the pixel region in a plan view, and
in the aligning of the donor substrate and the display substrate, the donor substrate is disposed such that the transfer layer faces the first electrode.

13. The method of claim 12, wherein the transferring of the transfer layer to the display substrate comprises:
transferring a hole transport region onto the first electrode;
transferring an emission layer onto the hole transport region; and
transferring an electron transport region onto the emission layer.

14. A method for manufacturing a display device, the method comprising:
preparing a base substrate on which a pixel region is defined;
forming a first electrode corresponding to the pixel region on a first surface of the base substrate;
forming a pixel defining film on the first electrode such that the pixel defining film exposes a portion of the first electrode;
disposing a donor substrate including a base layer and a transfer layer directly disposed on the base layer and including an organic material such that the transfer layer faces the first electrode; and
forming an organic pattern on the first electrode from the transfer layer by irradiating a laser toward the donor substrate on a second surface placed opposite to the first surface of the base substrate.

15. The method of claim 14, wherein the base substrate and the donor substrate are spaced apart from each other by a distance.

16. The method of claim 14, further comprising:
contacting the donor substrate to the base substrate prior to the forming of the organic pattern on the first electrode.

17. A device for manufacturing a display device, the device comprising:
a stage on which a display substrate having a pixel region is placed;
a donor substrate spaced apart from the display substrate and including a base layer and a transfer layer disposed on the base layer and including an organic material; and
a laser irradiation portion spaced apart from the donor substrate with the display substrate between the laser irradiation portion and the donor substrate and irradiating the donor substrate with a laser on the display substrate.

18. The device of claim 17, wherein the laser irradiation portion comprises a vertical cavity surface emitting laser (VCSEL).

19. The device of claim 17, wherein the laser irradiation portion irradiates a portion of the donor substrate, which overlaps the pixel region in a plan view, with the laser.

20. The device of claim 17, wherein the laser irradiation portion continuously moves on the display substrate and irradiates the donor substrate with the laser.
